(19) United States
(12) Patent Application Publication
(10) Pub. No.: US 2005/0162830 A1
(43) Pub. Date: Jul. 28, 2005

(54) Electronic system with a simplified enclosure

(75) Inventors: Michael Wortman, Sacramento, CA (US); Brendan Voge, Granite Bay, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: Hewlett-Packard Development Company, L.P., Houston, TX (US)

(21) Appl. No.: 10/767,528

(22) Filed: Jan. 27, 2004

(51) Int. Cl. H05K 7/20

(52) U.S. Cl. 361/695

(57) ABSTRACT

An electronic system comprises an enclosure and a backplane coupled inside the enclosure. The backplane has a plurality of slots capable of receiving a plurality of modules of various number and functionality. The modules include power modules, cooling modules, and function modules that are capable of plug insertion into the backplane slots. The backplane receives power and signal connections from external to the enclosure via the modules rather than internal cabling.

### BACKGROUND OF THE INVENTION

Organizations that rely on information technology are highly aware that system downtime leads to lost customers, lost profit, and a soiled reputation. System availability, reliability, and serviceability define the capability of on-line enterprise to service customers and fulfill business promises.

Reliability is a fundamental aspect of availability and is attained using components and operating methods that reduce the probability of system failure, thereby increasing system availability, maintaining data integrity, and reduces or minimizes the occurrence of corrupted data. Reliability can be increased by careful design of a system and selection of system components.

Availability is the time a system is accessible and operable. Availability generally improves as a consequence of reliability advancements since the more resistant a system is to failure, the more likely the system is to remain available. Availability can also be increased by reducing failure recovery time, and increasing the accuracy of diagnosis and/or reducing repair time.

Serviceability relates to the time, effort, and cost expended in isolating and repairing a system fault and restoring the system to utility. Serviceability depends on many disparate aspects of system design including packaging, accessibility to internal system components and subassemblies, accessibility and availability of replacement components, existence and accuracy of diagnostic signals and capabilities, presence and capability of automatic diagnostic functionality, and many others.

Various techniques have been used to improve reliability, availability, and serviceability including configuration of redundant systems, enabling system upgrades such as processors, storage, input/output, and the like without interrupting a running system, support of dynamic reconfiguration, and remotely monitoring operations. Many of the techniques and design practices can add substantially to system costs.

### SUMMARY

According to various embodiments, an electronic system comprises an enclosure and a backplane coupled inside the enclosure. The backplane has a plurality of slots capable of receiving a plurality of modules. The modules include power modules, cooling modules, and function modules that are capable of plug insertion into the backplane slots. The backplane receives power and signal connections from external to the enclosure via the modules rather than internal cabling.

### BRIEF DESCRIPTION OF THE DRAWINGS

Embodiments of the invention relating to both structure and method of operation, may best be understood by referring to the following description and accompanying drawings.

FIG. 1 is a pictorial block diagram that shows an embodiment of an electronic system with a simplified flexible and serviceable computer enclosure.

FIG. 2 is a pictorial block diagram illustrating a second embodiment of an electronic system including a simplified highly flexible and serviceable computer enclosure.

### DETAILED DESCRIPTION

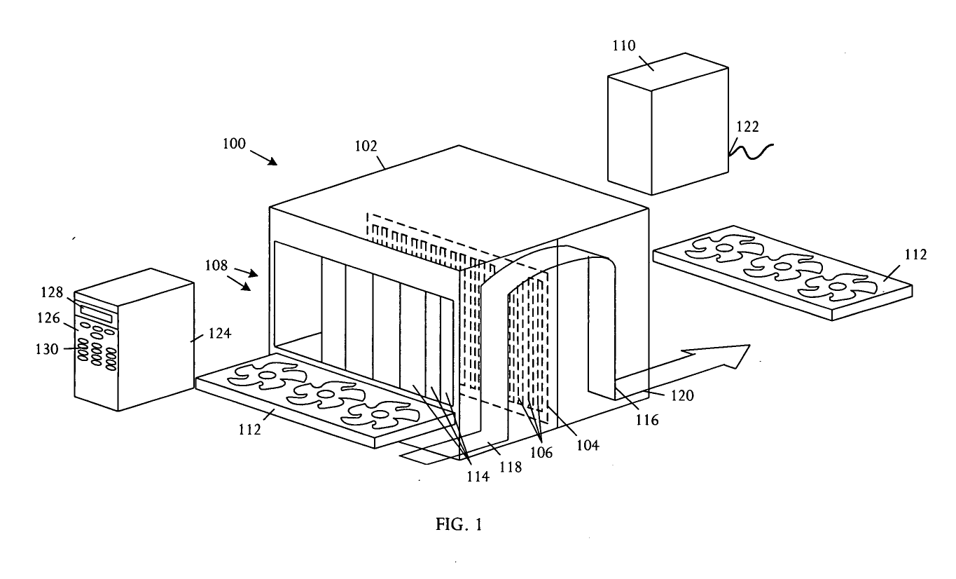

Referring to FIG. 1, a pictorial block diagram shows an embodiment of an electronic system 100 with a simplified flexible and serviceable computer enclosure 102. The electronic system 100 comprises the enclosure 102 and a backplane 104 in the generally form of a plane and having opposing first and second planar sides. The backplane 104 intersects the enclosure 102 and has a plurality of slots 106 on both the first and second planar sides. The slots 106 on both sides of the backplane 104 are capable of receiving multiple modules 108. The electronic system 100 accommodates modules 108 of multiple types and functionalities. The various types of modules 108 include power modules 110, cooling modules 112, and various types of function modules 114, all of which are capable of insertion into backplane slots 106. The backplane 104 receives power and signal connections from external to the enclosure 104 via the modules 108 so that internal cabling can be omitted. In the illustrative embodiments, various types of modules 108, other than the cooling modules 112, have a substantially common height and depth, and are an integral number of slots wide. In some embodiments, all modules 108 use identical ejectors and are color-coded.

In some embodiments, the enclosure 102 is constructed from sheet metal and is in the form of a simple box, such as a rectangular or square box. The illustrative enclosure 102 has an airspace illustrated by airflow 116 through the enclosure 102. The airflow 116 passes through an inlet plenum 118 at the front of the enclosure 102 and an output plenum 120 at the rear of the enclosure 102. The illustrative enclosure 102 is arranged to accept two cooling modules 112, one at the lower frontal area of the enclosure 102 overlying the input plenum 118, and one at the lower rear area of the enclosure 102 overlying the output plenum 120. The cooling modules 112 are plug insertable into the backplane 104 with one cooling module inserted into each of the respective sides of the backplane 104. Optimum or redundant system cooling is generally attained with two cooling modules 112 utilized in a push-pull configuration with the one, typically the rear, module 112 in an inverted position. The electronic system 100 can also be used with a single cooling module 112 insertable into either of the respective sides of the backplane 104.

The modules 108 are typically inserted in card cages that are mounted above the fans in the cooling modules 112 in both the first and second sides of the backplane 104. Modules 108 inserted into the front and back sides of the enclosure 102 are separated by the backplane 104 that has a connector for each module slot 106.

The electronic system 100 is easily configurable and can be configured to order by selection of a desired mix of modules 108. The modules 108 can perform a variety of widely different functions and typically can be selected from among graphics modules, input/output (I/O) modules, Uninterrupted Power Supply (UPS) modules, storage modules, server modules, switch modules, processor modules, memory modules, and combinational modules combining functionality of a plurality of function modules.

The electronic system 100 includes one or more power modules 110 that can be plugged into slots 106 in the backplane 104. The power module 110 has a power inlet 122 for receiving system power in a configuration for alternating current (AC) power and/or direct current (DC) power. The power modules 110 form modular configuration power supplies that are configured to enable supply of additional power and/or support a redundant power capability by addition of extra power modules 110. Power supply modules 110 are typically, but not necessarily, located in the rear portion of the enclosure 102.

The electronic system 100 has a simple cooling arrangement that supplies cooling for all modules 108 in the same manner. The modules 108 typically have the form of planar boards such as printed circuit cards that are mounted in a row of parallel boards inserted into the backplane 104 on the frontal and rear sides of the backplane 104. Air flows over the card or cards in each module 108 to form an unobstructed airway between the input plenum 118 and the output plenum 120. A frontal cooling module 112 draws air into the first plenum airspace 116 on the frontal side of the enclosure 102 and draws cooling air into the input plenum 118 and up through the modules 108 on the front side of the enclosure 102 to the airspace in the output plenum 120 within the enclosure 102 and overlying the modules 108 and the backplane 104. The cooling airflow proceeds down through the airspaces between the modules 108 on the rear side of the enclosure to the output plenum 120 and is pulled out of the enclosure 102 by fans of the rear cooling module 112.

In an illustrative embodiment, the rear cooling module 112 can be identical to the front cooling module 112, although the rear module 112 is installed in an inverted arrangement in relation to the frontal cooling module 112 so that the frontal module pushes airflow into the enclosure 102 and the rear module pulls the airflow outward. A capability to use the same cooling modules 112 for both the frontal and rear enclosure locations enables versatility, and reduces the number of separate items in inventory, thereby reducing inventory management costs. Heated air removed from the rear section of the enclosure 102 is relatively distant to the air inlet on the front of the enclosure 102 so that heated air is unlikely to be drawn into the input plenum 118 and recirculated.

The illustrative electronic system 100 also has a display and control module 124 that is also plug insertable into one or more backplane slots 106. The display and control module 124 has a user interface 126 for display and input functionality. The display and control module 124 has the height, depth, and width dimension specifications of the other modules 108. The display and control module 124 has a display 128, for example a liquid crystal display (LCD), light emitting diode (LED), or other status indicator. The display and control module 124 also has input keys 130 that can have functionality that ranges from menu control for the display 128 to keys for numeric and/or alphanumeric input entry.

Some embodiments can utilize a microphone for audio entry of commands and/or data. The display and control module 124 can be configured to support biometric security capabilities. The display and control module 124 functions as an interface for a user to manage operations of the individual modules 108. Multiple display and control modules 124 can be installed in an enclosure 102 to enhance reliability and availability by redundancy.

In an illustrative embodiment, the power modules 110 and the various types of function modules 114, including display and control modules 124, are capable of insertion into the same backplane slots 106. The backplane can manage power and signal lines that carry different voltages and currents by various techniques. Typically, particular backplane pins may be reserved for connection to a particular class of lines, for example, high voltage or high current lines. In some examples, all backplane pins may be configured to manage all appropriate ranges of electric conditions.

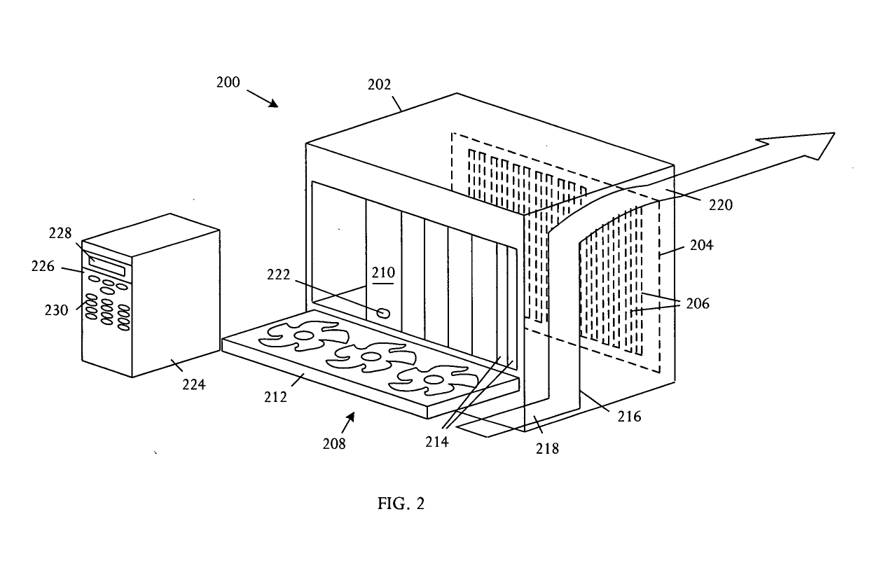

Referring to FIG. 2, a schematic pictorial diagram illustrates a second embodiment of an electronic system 200 including a simplified highly flexible and serviceable computer enclosure 202. The electronic system 200 comprises the enclosure 202 and a backplane 204 contained within and coupled inside the enclosure 202. The backplane 204 has multiple slots 206 capable of receiving a plurality of modules 208. The modules include power modules 210, cooling modules 212, and function modules 214 that are capable of plug insertion into the backplane slots 206.

The backplane 204, or system circuit board, has a simple structure comprising connectors for each of the slot locations to connect signal and power lines.

The illustrative enclosure 202 contains a plenum airspace 216 including an input plenum 218 and an output plenum 220. The plenum is a space for air circulation that is generally used for cooling of internal system components. System cooling is supplied by a cooling module 212 that is capable of plug insertion into a backplane slot 206 adjacent to the plenum airspace 216.

In the illustrative system 200, the various modules 208 are shown is solid and dotted lines entered into the enclosure 202 and inserted into the backplane 204, including a power module 210 and function modules 214 that perform various operations and functions. The modules 208 generally are configured in the form of planar boards, such as printed circuit cards, so that modules 208 are inserted into the backplane 204 with cards aligned in parallel leaving space between the cards and forming an unobstructed airway that extends from the input plenum 218 and the output plenum 220. In the illustrative system 200, the modules 208 have a substantially common height and depth and have a variable width that corresponds to an integral number of slots 206.

The system 200 can accommodate multiple types of function modules 214. Common types of function modules 214 that can be used in the system 200 include graphics modules, input/output (I/O) modules, Uninterrupted Power Supply (UPS) modules, storage modules, server modules, switch modules, processor modules, memory modules, combinational modules combining functionality of multiple function modules such as compute blades with a central processing unit (CPU), memory, and input/output, and others.

One or more power modules 210 are inserted into a backplane slot 206 and have a power inlet 222 for receiving system power in a configuration for alternating current (AC) power and direct current (DC) power. In the illustrative system 200 the power module 210 has a height and depth that are substantially the same or similar to the height and depth of other function modules 208.

The system also includes a display and control module 224 that is also plug insertable into one or more backplane slots 206. The display and control module 224 comprises a user interface 226 including a display 228 of data and status, and an input device 230. The display and control module 230 conforms to height and depth specifications of the other modules 208 and generally has a width that spans an integral number of slots 206.

The illustrative systems have enhanced flexibility by virtue of the ability to customize the system by the types and numbers of modules inserted. System availability is enhanced by reduction in service time due to module service access. System maintenance costs can be reduced by enabling user serviceable modules, thereby avoid the necessity for trained personnel to service the system.

The described electronic systems and enclosures are highly versatile and can be configured to specific requirements of a particular user. For example, a configuration for computer graphics rendering may include multiple high power processor modules, multiple storage and memory modules, and multiple graphics modules. A configuration for a large database may include a very large number of storage units, a mirror data site, and redundant control and display operations.

One aspect of the illustrative electronic systems and enclosures is simplicity of interconnection between modules. In some configurations, all modules including cooling modules, power modules, display and control modules, and function modules, are plug insertable into the backplane. Accordingly, essentially all internal connections are made through the backplane. Some configurations can include no internal connections other than the backplane connections. A configuration with all modules pluggable into the backplane eliminates cable harnesses and small assemblies that can obstruct airflow and hinder system cooling, complicate the insertion and arrangement of modules, introduce points of weakness in internal interconnections, and increase manufacturing and service costs.

Some configurations can include limited internal interconnections to status light emitting diodes (LEDs) located above the individual slots. In one example, LEDs for individual slots can be located at the top of a backplane and coupled to display apertures at the front and rear of the enclosure with optical light pipes.

In various embodiments, the system can be designed for high serviceability, reliability, and redundancy. Although a single cooling tray can be used to cool the system, a typical system has two trays, supplying a redundant cooling capability. The cooling airflow configuration is formed so that removing a single cooling fan tray for servicing does not cause an air bleed that impairs or diminishes system cooling.

Functional modules can be selected and arranged in the system to supply redundant functionality. Accordingly, high availability can be established by configurations with redundancy in all functional elements. The backplane or system circuit board is the only single point of failure. However, the backplane can be a highly simplified structure that is composed of durable and simple elements including connectors for the individual slot locations for communicating signals and power lines, and status LEDs. A simplified backplane structure enables a robust, essentially zero service subassembly. The backplane can further enhance availability in a configuration that is easily removed from the front of the enclosure in the highly rare event of servicing or failure.

The illustrative simplified, highly flexible, and serviceable computer enclosure has a simplified assembly that can eliminate internal cabling. The system can be configured with redundant cooling, power, control functions, functionality, and the like. The system is highly serviceable in many instances capable of user servicing. The system is highly configurable and can generally be easily configured to order. In many embodiments, the system is highly scalable and facilitates simple capacity increases by adding additional modules that are easily entered through front and/or back panels to the enclosure.

While the present disclosure describes various embodiments, these embodiments are to be understood as illustrative and do not limit the claim scope. Many variations, modifications, additions and improvements of the described embodiments are possible. For example, those having ordinary skill in the art will readily implement the steps necessary to provide the structures and methods disclosed herein, and will understand that the process parameters, materials, and dimensions are given by way of example only. The parameters, materials, and dimensions can be varied to achieve the desired structure as well as modifications, which are within the scope of the claims. Variations and modifications of the embodiments disclosed herein may also be made while remaining within the scope of the following claims. For example, the enclosure may be in any suitable size or shape. Various other appropriate materials may be used for any of the describe structures beyond what is described herein. The functionality and combinations of functionality of the individual modules can be any appropriate functionality.

1. An electronic system comprising:
an enclosure; and
a backplane coupled inside the enclosure and having a plurality of slots capable of receiving a plurality of modules, the modules including power modules, cooling modules, and function modules being capable of plug insertion into a backplane slot, the backplane receiving power and signal connections from external to the enclosure via the modules rather than internal cabling.

2. The electronic system according to claim 1 further comprising:
a plenum airspace including an input plenum and an output plenum.

3. The electronic system according to claim 2 further comprising:
a cooling module plug inserted into a backplane slot adjacent to the plenum airspace.

4. The electronic system according to claim 2 further comprising:
at least one module including power modules and function modules, and having an unobstructed airway between the input plenum and the output plenum.

5. The electronic system according to claim 1 further comprising:
at least one module including power modules and function modules having a substantially common height and depth and being an integral number of slots wide to enable both a flexible number and type of module within the enclosure, the power modules and function modules being capable of plug insertion into the same backplane slots.

6. The electronic system according to claim 5 further comprising:
at least one power module plug inserted into at least one backplane slot and having a power inlet for receiving system power in a configuration for alternating current (AC) power and direct current (DC) power, the at least one power module having a height and depth substantially common with the height and depth of function modules and being capable of plug insertion into backplane slots in common with function modules.

7. The electronic system according to claim 5 further comprising:
at least one display and control module plug inserted into at least one backplane slot and comprising a user interface for display and input functionality, the at least one display and control module having a height and depth substantially common with the height and depth of function modules and being capable of plug insertion into backplane slots in common with other function modules and power modules.

8. The electronic system according to claim 1 further comprising:
at least one function module plug inserted into at least one backplane slot, the function modules being selected from among a group comprising graphics modules, input/output (I/O) modules, Uninterrupted Power Supply (UPS) modules, storage modules, server modules, switch modules, processor modules, memory modules, and combinational modules combining functionality of a plurality of function modules.

9. An electronic system comprising:
an enclosure; and
a backplane having first and second planar sides, the backplane intersecting the enclosure and having a plurality of slots on both the first and second planar sides capable of receiving a plurality of modules, the modules including a plurality of module types and functionalities, the backplane receiving power and signal connections from external to the enclosure via the modules rather than internal cabling.

10. The electronic system according to claim 9 wherein:
the modules include power modules and function modules with substantially common height and depth and being an integral number of slots wide.

11. The electronic system according to claim 9 further comprising:
a first plenum airspace on a first end of the backplane and a second plenum airspace on a second end of the backplane, the first plenum including an input plenum and an output plenum so that cooling air circulates from the input plenum through modules on the first side of the backplane, through the second plenum, through modules on the second side of the backplane, and to the output plenum.

12. The electronic system according to claim 10 further comprising:
at least one cooling module plug inserted into a backplane slot of the plurality of backplane slots adjacent to the first plenum airspace.

13. The electronic system according to claim 9 further comprising:
a plurality of modules including power modules and function modules arranged in slots inserted into the first and second sides of the backplane, and having an unobstructed airway between the input plenum and the output plenum, the power modules and function modules being capable of plug insertion into the same backplane slots.

14. The electronic system according to claim 9 further comprising:
at least one power module plug inserted into at least one backplane slot and having a power inlet for receiving system power in a configuration for alternating current (AC) power and direct current (DC) power, the at least one power module having a height and depth substantially common with the height and depth of function modules and being capable of plug insertion into backplane slots in common with the function modules.

15. The electronic system according to claim 9 further comprising:
at least one display and control module plug inserted into at least one backplane slot and comprising a user interface for display and input functionality, the at least one display and control module having a height and depth substantially common with the height and depth of function modules.

16. The electronic system according to claim 9 further comprising:
at least one function module plug inserted into at least one backplane slot, the function modules being selected from among a group comprising graphics modules, input/output (I/O) modules, Uninterrupted Power Supply (UPS) modules, storage modules, server modules, switch modules, processor modules, memory modules, and combinational modules combining functionality of a plurality of function modules.

17. An electronic system comprising:
an enclosure;
a backplane having first and second planar sides, the backplane intersecting the enclosure and having a plurality of slots on both the first and second planar sides capable of receiving a plurality of modules, the backplane receiving power and signal connections from external to the enclosure via the modules rather than internal cabling; and
a first plenum airspace on a first end of the backplane and a second plenum airspace on a second end of the backplane, the first plenum including an input plenum and an output plenum so that cooling air circulates from the input plenum through modules on the first side of the backplane, through the second plenum, through modules on the second side of the backplane, and to the output plenum.

18. The electronic system according to claim 17 further comprising:
at least one cooling module plug inserted into a backplane slot adjacent to the first plenum airspace.

19. The electronic system according to claim 17 further comprising:
first and second cooling modules plug inserted into respective first side and second side backplane slots adjacent to the input plenum and the output plenum, respectively, and arranged in a push-pull configuration.

20. The electronic system according to claim 17 further comprising:
a plurality of modules including power modules and function modules arranged in slots inserted into the first and second sides of the backplane, the modules further comprising:
an unobstructed airway between the input plenum and the output plenum; and
at least one status light-emitting diode (LED) coupled a display panel on the enclosure adjacent the module.

21. The electronic system according to claim 17 further comprising:
at least one power module plug inserted into at least one backplane slot and having a power inlet for receiving system power in a configuration for alternating current (AC) power and direct current (DC) power, the at least one power module having a height and depth substantially common with the height and depth of function modules, and capability of insertion into backplane slots in common with the function modules.

22. The electronic system according to claim 17 further comprising:
at least one display and control module plug inserted into at least one backplane slot and comprising a user interface for display and input functionality, the at least one display and control module having a height and depth substantially common with the height and depth of function modules.

23. The electronic system according to claim 17 further comprising:
at least one function module plug inserted into at least one backplane slot, the function modules being selected from among a group comprising graphics modules, input/output (I/O) modules, Uninterrupted Power Supply (UPS) modules, storage modules, server modules, switch modules, processor modules, memory modules, and combinational modules combining functionality of a plurality of function modules.

24. An electronic system comprising:
means for enclosing a plurality of electronics components;
multiple means for electronically performing a function, ones of the multiple performing means being capable of performing functions selected from among a plurality of types and functions, the multiple performing means having a substantially common height and depth, and being an integral number of slots wide, enabling construction of a wide range of system configurations in terms of module function types and module function redundancy from a single set of modules and a single enclosure;
means for inserting and holding the multiple performing means, the inserting and holding means intersecting the enclosing means and being supplied with power and signal connections via the multiple function performing means rather than cabling; and
means for cooling interior to the enclosing means by circulating air around the inserting and holding means and through the multiple performing means.
